(19) United States
(12) Patent Application Publication
(10) Pub. No.: US 2008/0042207 A1
(43) Pub. Date: Feb. 21, 2008

(54) Contact array layout for improving ESD capability of CMOS transistors

(75) Inventors: Yi-Hsun Wu, Hsin-Chu (TW); Jian-Hsing Lee, Hsin-Chu (TW); Kuo-Feng Yu, Hsin-Chu City (TW); C.S. Tang, Hsinchu (TW); Cheng-Chun Ting, Hsinchu (TW)

Correspondence Address: L. Howard Chen, Esq.;Kirkpatrick & Lockhart Preston Gates Ellis LLP, Suite 1700, 55 Second Street, San Francisco, CA, 94105, US

(73) Assignee: Taiwan Semiconductor Manufacturing Co., Ltd.

(21) Appl. No.: 11/506,948

(22) Filed: Aug. 17, 2006

(51) Int. Cl. H01L 23/62

(52) U.S. Cl. 257/357

(57) ABSTRACT

A transistor layout is disclosed for improving electrostatic discharge capabilities. The layout has a first gate region with a first active region and a second active region formed on two sides thereof, and a second gate region placed next to the second active region with a third active region placed on an opposing side of the second gate region from the second active region. A first and a second set of contacts formed on the first and the third active regions, and a third set of contacts formed on the second active region, wherein the third set of contacts are spaced in parallel with and offset from the other two sets of contacts such that no contact from the third set is aligned laterally with a contact from either the first or the second set of contacts.

### BACKGROUND

The present invention relates generally to an integrated circuit (IC) design, and more particularly to a system of contact and via layout design used for a complementary metal-oxide-semiconductor (CMOS) circuit with improved electrostatic discharge (ESD) capabilities.

A complementary metal-oxide-semiconductor (CMOS) circuit, comprised of both a PMOS transistor and an NMOS transistor, is a widely used type of semiconductor device used in many battery-powered devices today due to its low power consumption capabilities. With the metal-oxide-semiconductor (MOS) transistors within a CMOS circuit, electrostatic discharge (ESD) can be a major reliability concern. A gate oxide of a MOS transistor of an integrated circuit (IC) is most susceptible to damage caused by ESD. The gate oxide may be destroyed by being contacted with a voltage only a few volts higher than a supply voltage. Electrostatic voltages from common environmental sources can easily reach thousands, or even tens of thousands of volts. Such voltages are destructive even though the charge and any resulting current are extremely small.

For this reason, CMOS circuits should be designed with good ESD capabilities to prevent itself from being damaged by ESD currents. However, the conventional layout structure used for creating contacts and vias of a CMOS circuit provides poor ESD capabilities since metal contacts within the drain and sources are lined up horizontally, directly facing each other. This provides a short and concentrated current path from the drain contacts to the source contacts, thereby allowing the ESD current to easily punch-through the transistor during an ESD event. This punch-through reduces the ability to contain the ESD current during an ESD event.

It is desirable to design a new layout structure for placement of contacts and vias for a CMOS circuit that can enhance ESD capabilities.

### SUMMARY

In view of the foregoing, this invention provides a contact and via layout design used for a CMOS circuit with improved ESD capabilities.

In one embodiment of the present invention, the layout has a first gate region with a first active region and a second active region formed on two sides thereof, and a second gate region placed next to the second active region with a third active region placed on an opposing side of the second gate region from the second active region. A first and a second set of contacts formed on the first and the third active regions, and a third set of contacts formed on the second active region, wherein the third set of contacts are spaced in parallel with and offset from the other two sets of contacts such that no contact from the third set is aligned laterally with a contact from either the first or the second set of contacts. This configuration avoids to let the ESD current flow directly from a contact to another horizontally, which can lead to punch-through.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 illustrates a conventional layout structure used for creating contacts or vias of a CMOS circuit.

FIG. 2 illustrates a layout structure used for creating contacts or vias of a CMOS circuit with improved ESD capabilities in accordance to one embodiment of the present invention.

### DESCRIPTION

The present disclosure provides a contact and/or via layout design used for a CMOS circuit with improved ESD capabilities.

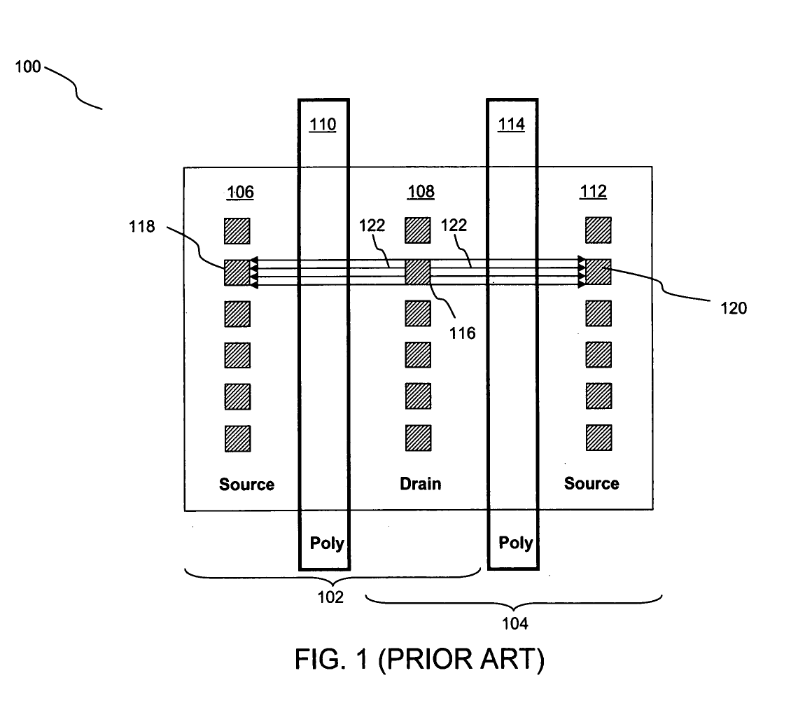

FIG. 1 illustrates a conventional layout structure 100 used for creating contacts and/or vias of a CMOS circuit. This conventional layout structure 100 is simplified to show a CMOS circuit that has two metal-oxide-semiconductor (MOS) transistors 102 and 104. Each of the MOS transistors 102 and 104 has a gate region with an implantation of P-type or N-type material formed on both sides of the gate region. For the MOS transistor 102, a source 106 and a drain 108 are formed on the two opposing sides of gate region 110. For the MOS transistor 104, a source 112 and the drain 108 are placed on the two opposing sides of another gate region 114. The gate region 110 or 114 are largely made of poly materials.

In this example, the two MOS transistors 102 and 104 commonly share the drain 108. The type of materials used for forming the drain 108 and the sources 106 and 112 of the MOS transistors 102 and 104 are determined according to the type of the MOS transistor being created. For example, if the MOS transistor 102 is a NMOS transistor, the implantations on the both sides of the poly material 110 will be made of N-type materials. The poly materials 110 and 114 used for creating the gate-structures of the two MOS transistors 102 and 104 will be placed between the source and the drain of the relevant MOS transistor over the entire transistor.

A set of contacts are placed onto the sources 106 and 112 and the drain 108 to provide connections between the sources or drains of the MOS transistor with vias of layers above. The conventional layout structures used for placing these contacts are designed to place the metal depositions along a same horizontal line for the entire transistor where the contacts on the drain 108 and the contacts on the sources 106 and 112 are lined up directly facing each other, thereby creating the shortest possible distance between each other. For example, a contact 116 on the drain 108 is lined up directly across from a contact 118 on the source 106 and a contact 120 on the source 112.

During an ESD event, the conventional layout structure 100 may create a set of concentrated ESD current paths 122 between the contacts laterally. These concentrated ESD current paths 122 may cause the ESD current to directly punch-through from the contacts of the drain 108 to the contacts of the sources 106 or 112, the effect of which is a significant degradation of ESD performance. Experiments have shown that for devices made by 0.13 um processing terminology, the punch-through may happen at about 175 volts of stress.

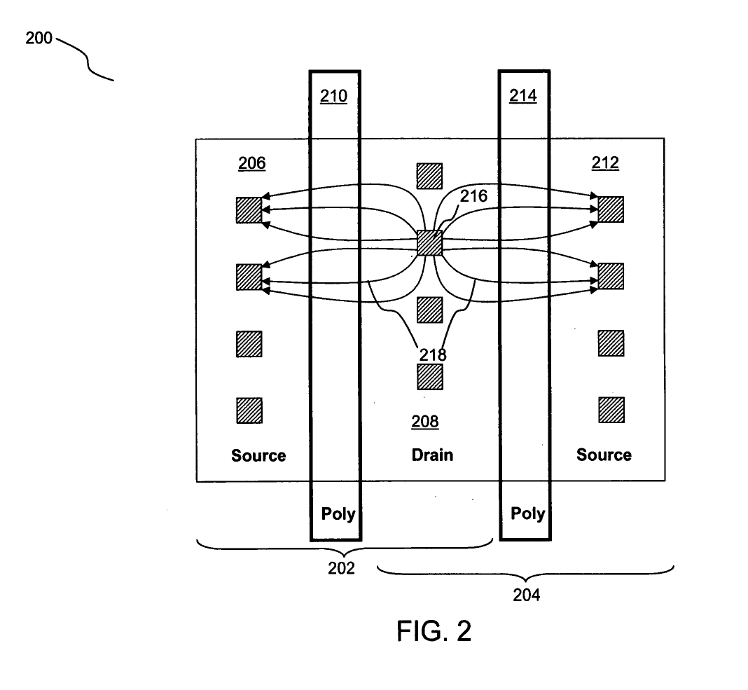

FIG. 2 illustrates a layout structure 200 used for creating contacts and/or vias of a CMOS circuit with improved ESD capabilities in accordance to one embodiment of the present invention. Like the layout structure 100 shown within FIG. 1, the layout structure 200 shows a CMOS circuit having two metal-oxide-semiconductor (MOS) transistors 202 and 204. Each of the MOS transistors 202 and 204 has a gate region with an implantation of P-type or N-type material formed on both sides of the gate region 210. For the MOS transistor 202, a source 206 and a drain 208 are formed on the two opposing sides of a gate region 210. For the MOS transistor 204, a source 212 and the drain 208 are placed on the two opposing sides of another gate region 214.

In this example, the two MOS transistors 202 and 204 commonly share the drain 208. The type of materials used for forming the drain 208 and the sources 206 and 212 of the MOS transistors 202 and 204 are determined according to the type of the MOS transistor being created. For example, if the MOS transistor 202 is a NMOS transistor, the implantations on the both sides of the poly material 210 will be made of N-type materials. The poly materials 210 and 214 used for creating the gate regions of the two MOS transistors 202 and 204 will be placed between the source and the drain of the relevant MOS transistor over the entire transistor.

Three sets of conductive contacts such as metal contacts are formed onto the sources 206 and 212 and the drain 208 to provide connections between the sources or drains of the MOS transistor with the vias of layers above. The spacing of the depositions of the contacts are spread out widely, thereby providing a larger spacing between the contacts of the drain 208 and the contacts of the sources 206 and 212. That is, although the three sets of contacts are placed parallel to each other, they are purposefully offset from each other vertically so that no single contact on the drain is laterally aligned with another contact from either source side. For example, unlike the conventional art, the contacts 206, 208, and 212 are no longer lined up laterally. In some cases, contacts 206 and 212 may not be aligned laterally as well. This layout arrangement does not provide a “straight line” ESD current path through all laterally aligned contacts. This helps to lessen the chance that the ESD current will punch-through directly between the contacts laterally. In addition, due to the offset between the different sets of contacts, the vertical contact-to-contact distance within a set of contacts may be larger than the minimum distance defined by the design rules.

For example, a contact 216 on the drain 208 is now much farther apart from closest contacts on the sources 206 and 212 since they are not aligned together anymore. Since the distance between each contact is farther apart with this layout structure, when an ESD event occurs, the ESD current flow will travel in all directions, instead of only laterally. By lessening the possibility of the ESD current punching through from the drain contacts to the source contacts, the ESD capability is greatly enhanced. Experiments have shown that for 0.13 um processing technology, when the contact-to-contact distance on the same vertical column is kept between 0.5 or 2 um, the practical ESD capability of the layout structure 200 is approximately 100 volts above that of the layout structure 100.

This invention provides a contact and/or via layout design used for a CMOS circuit with improved ESD capabilities. By increasing the distance between the drain contacts and the source contacts, the possibility of ESD current punch-through from drain contact to the source contact is reduced. It is further noteworthy that no extra cost or chip area is needed for widening the contact spacing with this layout structure.

The above illustration provides many different embodiments or embodiments for implementing different features of the invention. Specific embodiments of components and processes are described to help clarify the invention. These are, of course, merely embodiments and are not intended to limit the invention from that described in the claims.

Although the invention is illustrated and described herein as embodied in one or more specific examples, it is nevertheless not intended to be limited to the details shown, since various modifications and structural changes may be made therein without departing from the spirit of the invention and within the scope and range of equivalents of the claims. Accordingly, it is appropriate that the appended claims be construed broadly and in a manner consistent with the scope of the invention, as set forth in the following claims.

What is claimed is:

1. A transistor layout for improving electrostatic discharge capabilities, the layout comprising:
a first gate region with a first active region and a second active region formed on two sides thereof;
a second gate region placed next to the second active region with a third active region placed on an opposing side of the second gate region from the second active region;
at least a first set of contacts formed on the first active region, wherein the contacts are spaced by a predetermined distance, thereby maintaining electric charges thereof under a predetermined minimum level;
at least a second set of contacts formed on the third active region, wherein the contacts are spaced by a predetermined distance, thereby maintaining electric charges thereof under a predetermined minimum level; and
at least a third set of contacts formed on the second active region,
wherein the third set of contacts are spaced in parallel with or offset from the other two sets of contacts such that no contact from the third set is aligned laterally with a contact from either the first or the second set of contacts.

2. The system of claim 1, wherein the first and second sets of contacts are not aligned laterally.

3. The system of claim 1, wherein the first gate region is for a first transistor and the second gate region is for a second transistor, and the first and second transistors are of different types.

4. The system of claim 1, wherein the gate regions are made of a poly material.

5. The system of claim 1, wherein a contact-to-contact vertical distance is larger than a minimum contact distance according to a predetermined design rule.

6. A transistor layout for improving electrostatic discharge capabilities, the layout comprising:
a first gate region with a first source and a first drain formed on two sides thereof;
a second gate region placed next to the first drain with a second source placed on an opposing side of the second gate from the first drain;
a first set of contacts formed on the first source, wherein the contacts are spaced by a predetermined distance, thereby maintaining electric charges thereof under a predetermined minimum level;
a second set of contacts formed on the second source, wherein the contacts are spaced by a predetermined distance, thereby maintaining electric charges thereof under a predetermined minimum level; and
a third set of contacts formed on the first drain,
wherein the third set of contacts are spaced in parallel with or offset from the other two sets of contacts such that no contact from the third set is aligned laterally with a contact from either the first or the second set of contacts.

7. The system of claim 6, wherein the first and second sets of contacts are not aligned laterally.

8. The system of claim 6, wherein the first gate region is for a PMOS transistor and the second gate region is for a NMOS transistor.

9. The system of claim 6, wherein the gate regions are made of a poly material.

10. The system of claim 6, wherein a contact-to-contact vertical distance is larger than a minimum contact distance according to a predetermined design rule.

11. A transistor layout for improving electrostatic discharge capabilities, the layout comprising:
a first gate region with a first source and a first drain formed on two sides thereof to form a PMOS transistor;
a second gate region placed next to the first drain with a second source placed on an opposing side of the second gate from the first drain to form a NMOS transistor;
a first set of contacts formed on the first source, wherein the contacts are spaced by a predetermined distance, thereby maintaining electric charges thereof under a predetermined minimum level;
a second set of contacts formed on the second source, wherein the contacts are spaced by a predetermined distance, thereby maintaining electric charges thereof under a predetermined minimum level;
a third set of contacts formed on the first drain,
wherein the third set of contacts are spaced in parallel with or offset from the other two sets of contacts such that no contact from the third set is aligned laterally with a contact from either the first or the second set of contacts, and
wherein a contact-to-contact vertical distance is larger than a minimum contact distance according to a predetermined design rule.

12. The system of claim 6, wherein the first and second sets of contacts are not aligned laterally.

13. The system of claim 6, wherein the gate regions are made of a poly material.

14. The system of claim 6, wherein the contacts are metal contacts.
